(19) United States
(12) Patent Application Publication
(10) Pub. No.: US 2025/0089208 A1
(43) Pub. Date: Mar. 13, 2025

(54) SYSTEMS AND METHODS FOR THERMAL MANAGEMENT OF ELECTRONIC DEVICES

(71) Applicant: Microsoft Technology Licensing, LLC, Redmond, WA (US)

(72) Inventors: Oscar FARIAS MOGUEL, Seattle, WA (US); Dennis TRIEU, Calgary (CA); Kathryn M. OSEEN-SENDA, Seattle, WA (US); Hien Anh THAI, Kirkland, WA (US)

(21) Appl. No.: 18/243,876

(22) Filed: Sep. 8, 2023

(51) Int. Cl. H05K 7/20

(52) U.S. Cl. CPC H05K 7/203; H05K 7/20236; H05K 7/20263; H05K 7/20272; H05K 7/20327; H05K 7/20409; H05K 7/20445; G06F 1/20

(57) ABSTRACT

A system may include an immersion working fluid having a flow direction. A system may include a heat extraction plate with an internal chamber therein. A system may include an internal working fluid positioned in the heat extraction plate. A system may include a heat sink in fluid communication with the internal chamber by at least one fluid conduit, wherein the heat sink is downstream from the heat extraction plate in the flow direction.

### BACKGROUND

### Background and Relevant Art

Computing devices can generate a large amount of heat during use. The computing components can be susceptible to damage from the heat and commonly require cooling systems to maintain the component temperatures in a safe range during heavy processing or usage loads. Different computing demands and applications produce different amounts of thermal energy and require different amounts of thermal management.

### BRIEF SUMMARY

In some aspects, the techniques described herein relate to a thermal management system including: an immersion working fluid having a flow direction; a heat extraction plate with an internal chamber therein; an internal working fluid positioned in the heat extraction plate; and a heat sink in fluid communication with the internal chamber by at least one fluid conduit, wherein the heat sink is downstream from the heat extraction plate in the flow direction.

In some aspects, the techniques described herein relate to a thermal management system including: a thermal management device including: a heat-extraction plate with an internal chamber therein; an internal working fluid positioned in the heat-extraction plate; a heat sink in fluid communication with the internal chamber; a vapor conduit providing fluid communication from a vapor port of the internal chamber to the heat sink; and a condensate conduit providing fluid communication from the heat sink to a condensate port of the internal chamber, wherein the vapor port is closer to the heat sink than the condensate port.

In some aspects, the techniques described herein relate to a method of thermal management including: orienting a thermal management device in an immersion working fluid with a remote heat sink positioned downstream in a flow direction from a heat-generating component; heating an internal working fluid of the thermal management device at a heat-extraction plate with heat from the heat-generating component; flowing hot internal working fluid from the heat-extraction plate to the remote heat sink; exhausting heat from the internal working fluid to the immersion working fluid at the remote heat sink; and flowing internal working fluid from the heat sink to the heat-extraction plate.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a side schematic representation of an immersion cooling system, according to at least one embodiment of the present disclosure.

FIG. 2 is a side schematic representation of an immersion cooling system with an external condenser, according to at least one embodiment of the present disclosure.

FIG. 3 is a perspective view of a thermal management device including a heat-extraction plate thermally coupled to a heat-generating component, according to at least one embodiment of the present disclosure.

FIG. 4-1 through FIG. 4-3 illustrate a thermal management device with a plurality of fluid conduits, according to at least one embodiment of the present disclosure.

FIG. 5 is a side cross-sectional view of a thermal management device, according to at least one embodiment of the present disclosure.

FIG. 6 is a side cross-sectional view of a thermal management device with a wicking structure, according to at least one embodiment of the present disclosure.

FIG. 7 is a side cross-sectional view of another thermal management device with one or more internal thermal features to facilitate transfer of heat from the heat-generating component to the internal working fluid, according to at least one embodiment of the present disclosure.

FIG. 8 is a front view of a thermal management device that may be used with immersion cooling thermal management systems, according to at least one embodiment of the present disclosure.

FIG. 9 is a front view of a thermal management device including a fluid pump, according to at least one embodiment of the present disclosure.

FIG. 10 is a flowchart illustrating a method of thermal management using a thermal management device, according to at least one embodiment of the present disclosure.

### DETAILED DESCRIPTION

The present disclosure relates generally to systems and methods for thermal management of electronic devices or other heat-generating components. A thermal management device immersed in the working fluid transfers heat from the heat-generating components to the working fluid. The thermal transfer rate to the working fluid is based partially on a temperature difference between the thermal management device coupled to the heat-generating component and the working fluid. For example, a larger temperature difference creates a higher thermal transfer rate. Positioning the heat exchanger or heat exchange structure in a cooler region of the working fluid can increase the thermal management capacity of a thermal management device. Efficient transfer of heat from the heat-generating component to an immersion working fluid can allow a greater thermal management capacity for the same surface area and/or volume of thermal management devices.

Thermal management devices, according to the present disclosure, may be used in an immersion cooling system to increase the efficiency of the immersion cooling system. Immersion chambers surround the heat-generating components in a liquid working fluid, which conducts heat from the heat-generating components to cool the heat-generating components. As the immersion working fluid absorbs heat from the heat-generating components, the temperature of the immersion working fluid increases. In some embodiments, the hot immersion working fluid can be circulated through the thermal management system to cool the immersion working fluid and/or replace the immersion working fluid with cool immersion working fluid. In some embodiments, the immersion working fluid vaporizes, introducing vapor into the liquid of the immersion working fluid which rises out of the liquid phase, carrying thermal energy away from the heat-generating components in the vapor phase via the latent heat of boiling.

In large-scale computing centers, such as cloud-computing centers, data processing centers, data storage centers, or other computing facilities, immersion cooling systems provide an efficient method of thermal management for many computing components under a variety of operating loads. In some embodiments, an immersion cooling system includes an immersion working fluid in an immersion chamber and a heat exchanger to cool the liquid phase and/or a condenser to extract heat from the vapor phase of the working fluid. The heat exchanger may include a condenser that condenses the vapor phase of the working fluid into a liquid phase and returns the liquid immersion working fluid to the immersion chamber. In some embodiments, the liquid immersion working fluid absorbs heat from the heat-generating components, and one or more fluid conduits direct the hot liquid immersion working fluid outside of the immersion chamber to a radiator, heat exchanger, or region of lower temperature to cool the liquid working fluid.

In some embodiments, a high-compute application assigned to and/or executed on the computing devices or systems in the immersion cooling system requires a large amount of thermal management. A dual phase immersion working fluid boiling absorbs heat to overcome the latent heat of boiling. The phase change from liquid to vapor, therefore, allows the working fluid to absorb a comparatively large amount of heat with a small or no associated increase in temperature. Further, the lower density allows the vapor to be removed from the immersion bath efficiently to exhaust the associated heat from the system.

In some embodiments, a thermal management system includes an immersion tank with a dual phase immersion working fluid positioned therein. The dual phase immersion working fluid receives heat from heat-generating components immersed in the liquid immersion working fluid, and the heat vaporizes the immersion working fluid, changing the immersion working fluid from a liquid phase to a vapor phase. The thermal management system includes a condenser, such as described herein, to condense the vapor immersion working fluid back into the liquid phase. In some embodiments, the condenser is in fluid communication with the immersion tank by one or more conduits. In some embodiments, the condenser is positioned inside the immersion tank.

In some embodiments, the thermal management capacity of a thermal management system is based at least partially on the efficient transfer of heat from the heat-generating components to the immersion working fluid. In space-constrained structures or assemblies, the size (surface area, mass, and/or volume) or the thermal efficiency of the heat sink or thermal management device in contact with the heat-generating component is limited. The ability for the thermal management device coupled to the heat-generating component is hindered. In some embodiments according to the present disclosure, a thermal management device includes an internal working fluid that transfers heat from the heat-generating component to a remote heat sink in a region of cooler immersion working fluid, a region with more space for a larger heat sink than would be possible proximate the heat-generating component, other benefits, or combinations thereof.

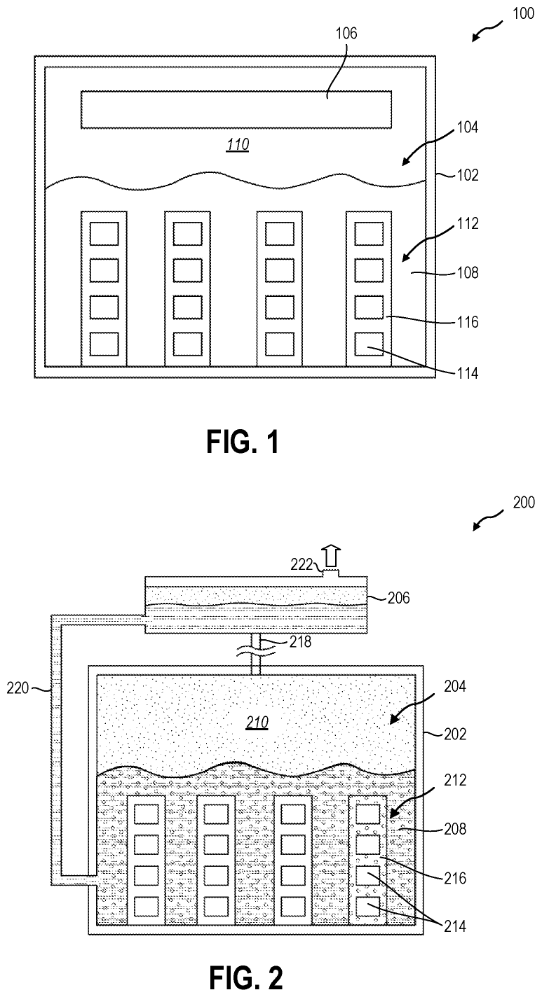

A conventional immersion cooling system 100, shown in FIG. 1, includes an immersion tank 102 containing an immersion chamber 104 and a condenser 106 or heat-exchanger in the immersion chamber 104. The immersion chamber 104 contains an immersion working fluid that has a liquid working fluid 108 and a vapor working fluid 110 portion. The liquid working fluid 108 creates an immersion bath 112 in which a plurality of heat-generating components 114 are positioned to heat the liquid working fluid 108 on supports 116.

Referring now to FIG. 2, in some embodiments, an immersion cooling system 200 includes an immersion tank 202 defining an immersion chamber 204 with an immersion working fluid positioned therein. An immersion working fluid in the immersion tank 202 has a boiling temperature that is at least partially related to one or more operating properties of the immersion cooling system, the electronic components and/or computing devices in the immersion tank 202, computational or workloads of the electronic components and/or computing devices in the immersion tank 202, external and/or environmental conditions, or other properties that affect the operation of the immersion cooling system 200.

In some embodiments, the immersion working fluid is a single-phase working fluid with a boiling temperature below an operating temperature of the heat-generating components 214 that allows the immersion working fluid to remain a liquid working fluid 208 throughout operation. In some embodiments, the immersion working fluid transitions between a liquid immersion working fluid 208 phase and a vapor immersion working fluid 210 phase to remove heat from hot or heat-generating components 214 in the immersion chamber 204. The liquid immersion working fluid 208 more efficiency receives heat from the heat-generating components 214 and, upon transition to the vapor immersion working fluid 210, the vapor immersion working fluid 210 can be removed from the immersion tank 202, cooled and condensed by the condenser 206 (or other heat exchanger) to extract the heat from the immersion working fluid, and the liquid immersion working fluid 208 can be returned to the liquid immersion bath 212.

In some embodiments, the immersion bath 212 of the liquid immersion working fluid 208 has a plurality of heat-generating components 214 positioned in the liquid immersion working fluid 208. The liquid immersion working fluid 208 surrounds at least a portion of the heat-generating components 214 and other objects or parts attached to the heat-generating components 214. In some embodiments, the heat-generating components 214 are positioned in the liquid immersion working fluid 208 on one or more supports 216. The support 216 may support one or more heat-generating components 214 in the liquid immersion working fluid 208 and allow the immersion working fluid to move around the heat-generating components 214. In some embodiments, the support 216 is thermally conductive to conduct heat from the heat-generating components 214. The support(s) 216 may increase the effective surface area from which the liquid immersion working fluid 208 may remove heat through convective cooling.

In some embodiments, the heat-generating components 214 include electronic or computing components or power supplies. In some embodiments, the heat-generating components 214 include computer devices, such as individual personal computer or server blade computers. In some embodiments, one or more of the heat-generating components 214 includes a thermal management device or other device attached to the heat-generating component 214 to conduct away thermal energy and effectively increase the surface area of the heat-generating component 214 according to embodiments of the present disclosure. In some embodiments, the thermal management device of the heat-generating component 214 includes an internal working fluid that flows through a fluid conduit connected to a remote heat sink away from the heat-generating component 214.

As described, conversion of the liquid immersion working fluid 208 to a vapor phase requires the input of thermal energy to overcome the latent heat of vaporization and may be an effective mechanism to increase the thermal capacity of the working fluid and remove heat from the heat-generating components 214. Because the vapor immersion working fluid 210 rises in the liquid immersion working fluid 208, the vapor immersion working fluid 210 can be extracted from the immersion chamber 204 in an upper vapor region of the chamber. A condenser 206 cools part of the vapor immersion working fluid 210 back into a liquid immersion working fluid 208, removing thermal energy from the system and reintroducing the immersion working fluid into the immersion bath 212 of the liquid immersion working fluid 208. The condenser 206 radiates or otherwise dumps the thermal energy from the immersion working fluid into the ambient environment or into a conduit to carry the thermal energy away from the cooling system.

In some embodiments of immersion cooling systems, a liquid-cooled condenser is integrated into the immersion tank and/or the chamber to efficiency remove the thermal energy from the working fluid. In some embodiments, an immersion cooling system 200 for thermal management of computing devices allows at least one immersion tank 202 and/or chamber 204 to be connected to and in fluid communication with an external condenser 206. In some embodiments, an immersion cooling system 200 includes a vapor return line 218 that connects the immersion tank 202 to the condenser 206 and allows vapor working fluid 210 to enter the condenser 206 from the immersion tank 202 and/or chamber 204 and a liquid return line 220 that connects the immersion tank 202 to the condenser 206 and allows liquid working fluid 208 to return to the immersion tank 202 and/or chamber 204.

The vapor return line 218 may be colder than the boiling temperature of the working fluid. In some embodiments, a portion of the vapor working fluid 210 condenses in the vapor return line 218. The vapor return line 218 can, in some embodiments, be oriented at an angle such that the vapor return line 218 is non-perpendicular to the direction of gravity. The condensed working fluid can then drain either back to the immersion tank 202 or forward to the condenser 206 depending on the direction of the vapor return line 218 slope. In some embodiments, the vapor return line 218 includes a liquid collection line or valve, like a bleeder valve, that allows the collection and/or return of the condensed working fluid to the immersion tank 202 or condenser 206.

In some embodiments, the liquid working fluid receives heat in a cooling volume of working fluid immediately surrounding the heat-generating components. The cooling volume is the region of the working fluid (including both liquid and vapor phases) that is immediately surrounding the heat-generating components and/or the thermal management device(s) thermally coupled thereto and is responsible for the convective cooling of the heat-generating components. In some embodiments, the cooling volume is the volume of working fluid within 5 millimeters (mm) of the heat-generating components and/or thermal management device(s).

The immersion working fluid has a boiling temperature below a critical temperature at which the heat-generating components experience thermal damage. The immersion working fluid can thereby receive heat from the heat-generating components to cool the heat-generating components before the heat-generating components experience damage.

For example, the heat-generating components may be computing components that experience damage above 100° Celsius (C). In some embodiments, the boiling temperature of the immersion working fluid is less than a critical temperature of the heat-generating components. In some embodiments, the boiling temperature of the immersion working fluid is less about 90° C. at 1 atmosphere of pressure. In some embodiments, the boiling temperature of the immersion working fluid is less about 80° C. at 1 atmosphere of pressure. In some embodiments, the boiling temperature of the immersion working fluid is less about 70° C. at 1 atmosphere of pressure. In some embodiments, the boiling temperature of the immersion working fluid is less about 60° C. at 1 atmosphere of pressure. In some embodiments, the boiling temperature of the immersion working fluid is at least about 35° C. at 1 atmosphere of pressure. In some embodiments, the working fluid includes water.

In some embodiments, the working fluid includes glycol. In some embodiments, the working fluid includes a combination of water and glycol. In some embodiments, the working fluid includes an aqueous solution. In some embodiments, the working fluid includes an electronic liquid, such as FC-72 available from 3M, or similar non-conductive fluids. In some embodiments, the heat-generating components, supports, or other elements of the immersion cooling system positioned in the working fluid have nucleation sites on a surface thereof that promote the nucleation of vapor bubbles of the working fluid at or below the boiling temperature of the working fluid.

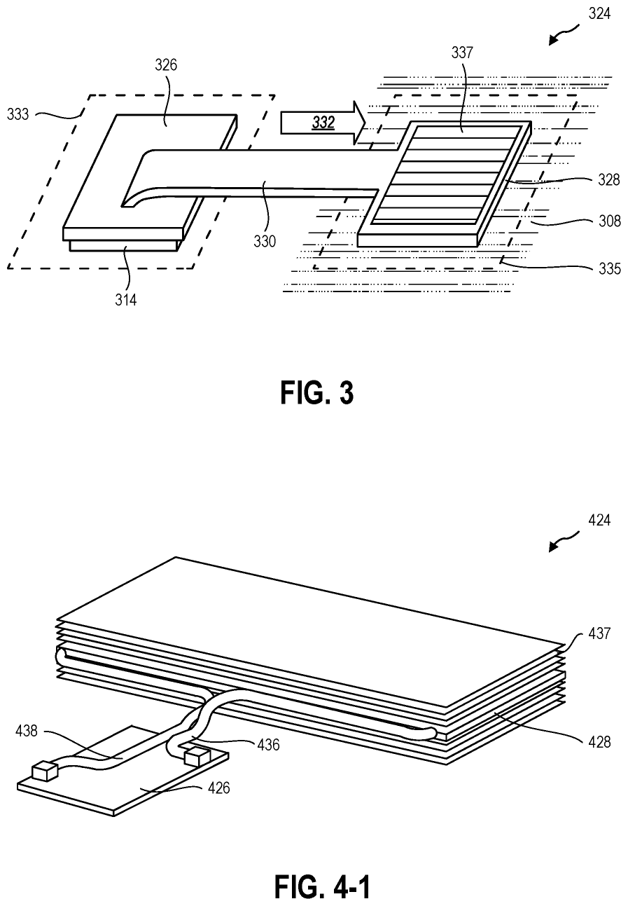

FIG. 3 is a perspective view of an embodiment of a thermal management device 324 including a heat-extraction plate 326 thermally coupled to a heat-generating component 314. While embodiments of thermal management devices will be described in relation to processors (e.g., central processing unit (CPU), graphical processing unit (GPU), physics processing unit, application specific integrated circuit (ASIC)), as described above, the heat-generating component 314 may be any heat-generating component in an immersion cooling system, such as a power supply, hardware storage device, networking or other communication device, etc. In some embodiments, the heat-extraction plate 326 is configured to be thermally coupled, at a proximal surface of the heat-extraction plate 326 of the thermal management device 324, to a heat-generating component 314. In some embodiments, the thermal management device 324 is directly coupled to the heat-generating component 314. For example, the thermal management device 324 may be directly contacting the heat-generating component 314 on a proximal surface of the heat-extraction plate 326. In some embodiments, the thermal management device 324 is indirectly thermally coupled to the heat-generating component 314. For example, the thermal management device 324 may be thermally coupled to the heat-generating component 314 by a thermal interface material, such as thermal paste, positioned between a proximal surface of the heat-extraction plate 326 of the thermal management device 324 and the heat-generating component 314. In some examples, the thermal management device 324 may be thermally coupled to the heat-generating component 314 by a liquid phase metal positioned between a proximal surface of the heat-extraction plate 326 of the thermal management device 324 and the heat-generating component 314. In some examples, the thermal management device may be thermally coupled to the heat-generating component 314 by a heat spreader positioned between a proximal surface of the heat-extraction plate 326 of the thermal management device 324 and the heat-generating component 314.

In some embodiments, the heat-extraction plate 326 is thermally coupled to a heat sink 328 by a fluid conduit 330. An internal working fluid inside the thermal management device 324 flows between the heat-extraction plate 326 and the heat sink 328 via the fluid conduit 330 to transfer heat from the heat-extraction plate 326 (received from the heat-generating component 314) to the remotely located heat sink 328.

In some embodiments, the heat sink 328 is positioned in a downstream flow direction 332 of a surrounding liquid immersion working fluid 308 (such as that described in relation to FIG. 1 and FIG. 2). In some embodiments, the heat sink 328 includes a plurality of thermal transfer features 337, such as fins, rods, pins, surface treatments, coatings, etc. that increase surface area, thermal transfer efficiency, vapor bubble nucleation, or otherwise facilitate the exhaustion of heat from the heat sink 328 to the liquid immersion working fluid 308. As described herein, in some embodiments, the liquid immersion working fluid 308 vaporizes into a vapor immersion working fluid 310. In some embodiments, the liquid immersion working fluid 308 remains in a liquid phase while increasing in temperature. By positioning the heat sink 328 downstream of the heat-extraction plate 326 in the flow direction 332 of the immersion working fluid, the first region 333 of the immersion working fluid proximate the heat-extraction plate 326 remains cooler than a second region 335 of the immersion working fluid proximate the heat sink 328, which allows the heat-generating component 314 to remain cooler and/or exhaust heat to the heat-extraction plate 326 and/or the immersion working fluid more efficiently.

FIG. 4-1 through FIG. 4-3 illustrate various views of another embodiment of a thermal management device 424 according to the present disclosure. In some embodiments, a thermal management device 424 includes a heat-extraction plate 426 thermally coupled to a heat sink 428 by a plurality of fluid conduits. In some embodiments, the fluid conduits include a vapor conduit 434 and a condensate conduit 436 that circulate a vapor phase of an internal working fluid from the heat-extraction plate 426 to the heat sink 428 and a liquid phase (i.e., condensate) of the internal working fluid from the heat sink 428 back to the heat-extraction plate 426. The heat-extraction plate 426 receives heat from heat-generation component to vaporize the internal working fluid, and the heat sink exhausts heat from the internal working fluid to condense the internal working fluid into a liquid phase.

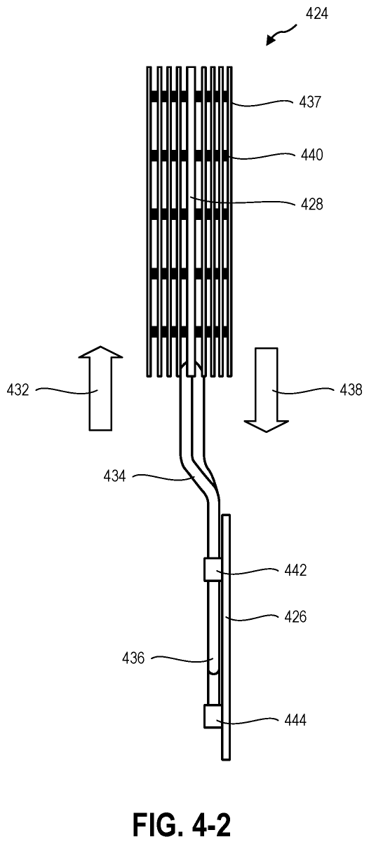

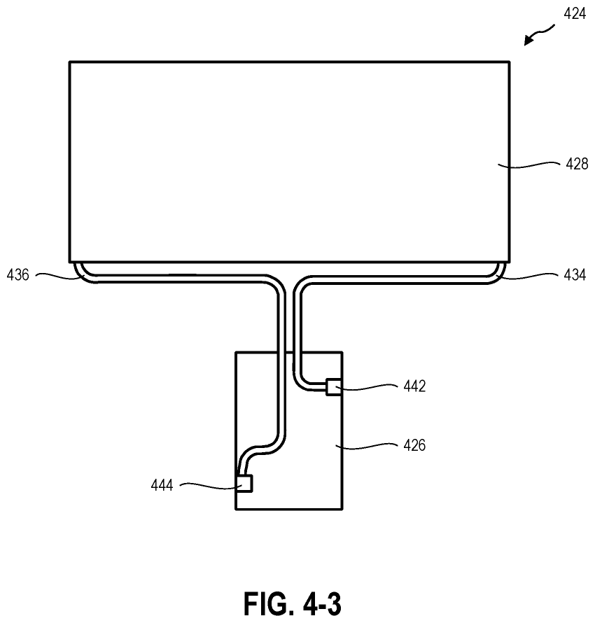

Referring now to FIG. 4-2, in some embodiments, the heat sink 428 circulates the internal working fluid through and/or past a plurality of thermal transfer features 437 to exhaust the heat to the immersion working fluid. In some embodiments, the heat sink 428 includes a combination of thermal transfer features 437, such as plates or fins that are thermally coupled by heat pipes 440 oriented transversely to the plates or fins.

In some embodiments, the thermal transfer features 437 are positioned in the flow direction 432 of the immersion working fluid and in a downstream direction from the heat-extraction plate 426. The heat exhausted from the heat sink 428 is therefore exhausted into the immersion working fluid downstream from the heat-extraction plate 426 and the heat-generating component.

In some embodiments, the thermal management device 424 is oriented at least partially vertically with respect to a gravitational direction 438. In some embodiments, the gravitational direction 438 and the flow direction 432 are substantially opposite one another. When the thermal management device 424 is oriented at least partially vertically with respect to a gravitational direction 438, the heat sink 428 is vertically above the heat-extraction plate 426 with respect to gravity, allowing the relative buoyancy of the vapor internal working fluid to move the vapor internal working fluid through the vapor conduit 434 toward the heat sink 428 and the relative density of liquid internal working fluid (condensate) to flow downward through the condensate conduit 436 toward the heat-extraction plate 426.

To further facilitate the thermal siphon of the thermal management device 424, in some embodiments, the vapor conduit 434 is connected to a vapor port 442 of the heat-extraction plate 426 and the condensate conduit 436 is connected to a condensate port 442 of the heat-extraction plate 426. The vapor port 442 and the condensate port 444 provide fluid communication to an internal chamber of the heat-extraction plate 426 at different locations relative to the heat sink 428. When oriented vertically relative to the gravitational direction 438, the vapor port 442 and the condensate port 444 are positioned at different vertical heights. In some embodiments, the vapor port 442 is located closer to the heat sink 428 than the condensate port 444. When oriented vertically relative to the gravitational direction 438, the vapor port 442 is vertically higher than the condensate port 444. The vertical relationship allows for a gravity-assisted passive circulation of the internal working fluid through the thermal management device 424.

FIG. 4-3 is a front view of the embodiment of a thermal management device 424 of FIG. 4-2 in the vertical orientation of FIG. 4-2. In some embodiments, a surface area of the heat sink 428 is greater than the surface area of the heat-extraction plate 426. In some embodiments, the surface area of the heat sink 428 is at least twice that of the surface area of the heat-extraction plate 426. In some embodiments, the surface area of the heat sink 428 is at least four times that of the surface area of the heat-extraction plate 426. In some embodiments, the surface area of the heat sink 428 is at least ten times that of the surface area of the heat-extraction plate 426.

The vapor port 442 is, in some embodiments, closer to the heat sink 428 than the condensate port 444. In some embodiments, the vapor conduit 434 is shorter in length than the condensate conduit 436. For example, the vapor conduit 434 between the vapor port 442 and the heat sink 428 is shorter than the condensate conduit 436 between the condensate port 444 and the heat sink 428. In at least one embodiment, the vapor conduit 434 connects to the heat sink 428 at a first side of the heat sink 428 and the condensate conduit 436 connects to the heat sink 428 at a second side of the heat sink 428 substantially opposite the first side.

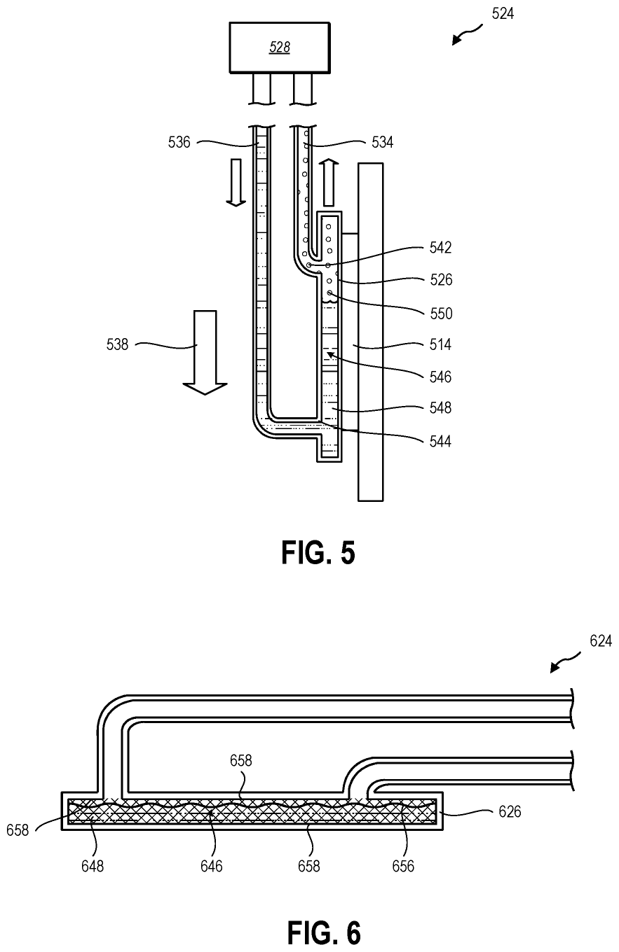

FIG. 5 is a side cross-sectional view of an embodiment of a thermal management device 524. In some embodiments, a heat-extraction plate 526 of the thermal management device 524 includes an internal chamber 546 that houses an internal working fluid, such as that described in relation to FIG. 3 through FIG. 4-3. In some embodiments, the internal working fluid is a dual phase working fluid with a liquid phase and a vapor phase during operation of the thermal management device 524. In some embodiments, the relative density of the liquid internal working fluid 548 and the vapor internal working fluid 550 causes the liquid internal working fluid 548 to settle at a bottom of the internal chamber 546 and the vapor internal working fluid 550 to rise to a top of the internal chamber relative to the gravitational direction 538. In some embodiments, the vapor port 542 is positioned on the heat-extraction plate 526 proximate the vapor portion of the internal chamber 546 containing the vapor internal working fluid 550. In some embodiments, the condensate port 544 is positioned on the heat-extraction plate 526 proximate the liquid portion of the internal chamber 546 containing the liquid internal working fluid 548.

In some embodiments, as the heat-extraction plate 526 and liquid internal working fluid receive heat from the heat-generating component 514, the internal working fluid changes state and the vapor pressure urges vapor internal working fluid 550 through the vapor port 542 into the vapor conduit 534. The vapor internal working fluid 550 flows through the vapor conduit 534 to the heat sink 528, where the heat sink 528 exhausts heat from the internal working fluid (e.g., to the immersion working fluid such as described in relation to FIG. 1 through FIG. 3) to condense the vapor internal working fluid 550 to the liquid phase. The condensation contributes to a pressure differential that further circulates the vapor working fluid 550 to the heat sink 528. In some embodiments, the liquid internal working fluid 548 then flows downward relative to the gravitational direction 538 through the condensate conduit 536 to the condensate port 544. Upon returning to the internal chamber 546, the liquid internal working fluid 548 is available to receive heat from the heat-generating component 514 and continue the passive circulation of internal working fluid.

In some embodiments, the heat sink 528 includes a condensation chamber or other fluid chamber or conduit with one or more condensation surface features configured to facilitate condensation of the internal working fluid. In some embodiments, the condensation surface features include pins, rods, fins, pipes, cones, or other surface features that increase surface area, thermal transfer efficiency, condensation rates, or otherwise facilitate the transfer of heat from the vapor internal working fluid 550 to condense the internal working fluid.

FIG. 6 is a side cross-sectional view of another embodiment of a thermal management device 624. In some embodiments, a wicking structure 656 is positioned in the internal chamber 646 of the heat-extraction plate 626. The wicking structure 656 wicks the liquid internal working fluid 648 into additional portions of the internal chamber 646 to receive heat through the heat-extraction plate 626. For example, less than the entire internal chamber 646 may have liquid internal working fluid 648 therein, and the wicking structure may draw the liquid internal working fluid in contact with or proximity to additional internal surfaces 658 of the heat-extraction plate 626 to more efficiently transfer heat to the liquid internal working fluid 648.

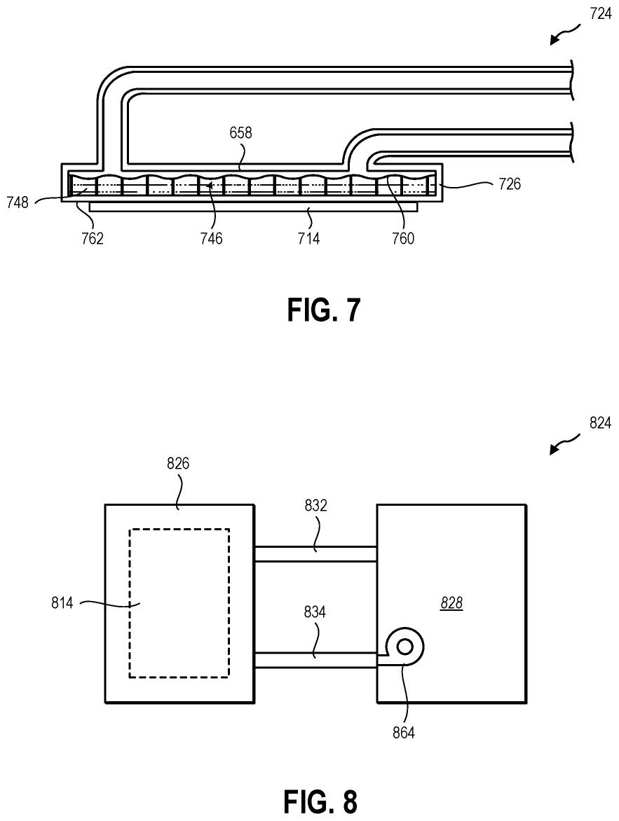

FIG. 7 is a side cross-sectional view of another embodiment of a thermal management device 724 with one or more internal thermal features 760 to facilitate transfer of heat from the heat-generating component 714 to the internal working fluid. In some embodiments, the internal thermal features 760 include pins, rods, fins, pipes, cones, or other surface features that increase surface area, thermal transfer efficiency, vapor bubble nucleation, or otherwise facilitate the transfer of heat to the liquid internal working fluid 748. In some embodiments, the internal thermal features 760 are positioned on an internal surface 758 proximate a contact surface 762 of the heat-extraction plate 726. The contact surface 762 is the surface of the heat-extraction plate 726 contacting or configured to contact the heat-generating component 714. As described herein, the contact surface 762, in some embodiments, directly contacts the heat-generating component. In some embodiments, the contact surface 762 is indirectly thermally coupled to the heat-generating component by a thermal interface material, such as a paste, gel, or liquid metal that conducts heat from the heat-generating component 714 to the contact surface 762.

While some embodiments of a thermal management device according to the present disclosure include a dual phase internal working fluid to passively circulate heat through the thermal management device, in some embodiments, the thermal management device is oriented relative to the gravitational direction such that active circulation is needed. In some embodiments, a single-phase internal working fluid is used in the thermal management device, and active circulation moves the internal working fluid through the fluid conduit between the heat-extraction plate and the heat sink.

FIG. 8 is a front view of another embodiment of a thermal management device 824 that may be used with immersion cooling thermal management systems, such as described in relation to FIG. 1 and FIG. 2. In some embodiments, the thermal management device 824 includes a fluid pump 864 to actively circulate an internal working fluid through the thermal management device 824. As described herein, in space-constrained embodiments, the heat sink 828 is located in a region with more space than is available adjacent to the heat-generating component 814. The heat sink 828, therefore, has the available volume to house the fluid pump 864 therein, in some embodiments.

In some embodiments, the internal working fluid is a single-phase working fluid. The heat-extraction plate 826 is thermally coupled to the heat-generating component 814 and a first fluid conduit 832 carries the hot internal working fluid from the heat-extraction plate 826 to the heat sink 828. In some embodiments, the fluid pump 864 then pumps the cooled internal working fluid from the heat sink 828 through a second fluid conduit 834 to the heat-extraction plate 826. In some embodiments, the internal working fluid is a dual phase working fluid, where the first fluid conduit 832 is a vapor conduit, and the second fluid conduit 834 is a condensate conduit 834.

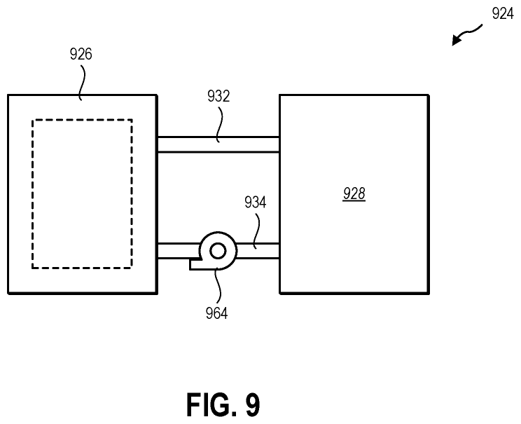

FIG. 9 is a front view of another embodiment of a thermal management device 924 including a fluid pump 964. In some embodiments, the fluid pump 964 is located in line with the second fluid conduit 934 to pump cooled internal working fluid from the heat sink 928 to the heat-extraction plate 926. In some embodiments, the heat sink 928 has greater thermal transfer capacity when the fluid pump 964 is located elsewhere in the thermal management device 924.

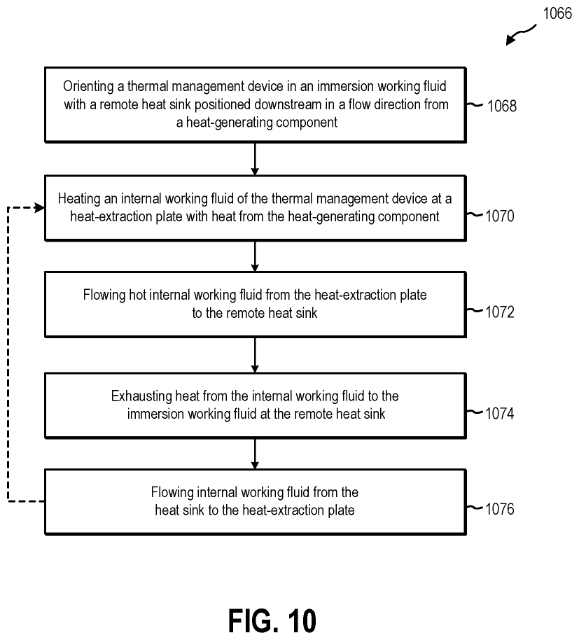

FIG. 10 is a flowchart illustrating an embodiment of a method 1066 of thermal management using a thermal management device according to the present disclosure. In some embodiments, the method 1066 includes orienting a thermal management device in an immersion working fluid with a remote heat sink positioned downstream in the flow direction from a heat-generating component at 1068. In some embodiments, the thermal management device is any embodiment of a thermal management device described herein. In some embodiments, the immersion working fluid is a single-phase immersion working fluid. In some embodiments, the immersion working fluid is a dual phase immersion working fluid. In some embodiments, orienting the thermal management device further includes orienting the heat sink above a heat-extraction plate of the thermal management device relative to a gravitational direction. In some embodiments, orienting the thermal management device further includes orienting the thermal management device in the flow direction where the flow direction is substantially opposite the gravitational direction.

The method 1066 further includes heating an internal working fluid of the thermal management device at a heat-extraction plate with heat from the heat-generating component at 1070. The method 1066, in some embodiments, includes flowing hot internal working fluid from the heat-extraction plate to the remote heat sink at 1072. In some embodiments, the hot internal working fluid is vapor internal working fluid. In some embodiments the hot internal working fluid is liquid internal working fluid.

The method 1066 further includes exhausting heat from the internal working fluid to the immersion working fluid at the remote heat sink at 1074. In some embodiments, exhausting heat from the internal working fluid includes lower a temperature of the internal working fluid. In some embodiments, exhausting heat from the internal working fluid includes condensing the internal working fluid. In some embodiments, the method 1066 includes flowing internal working fluid from the heat sink to the heat-extraction plate at 1076. In some embodiments, flowing internal working fluid from the heat sink to the heat-extraction plate includes allowing the internal working fluid to flow down a fluid conduit under the force of gravity. In some embodiments, flowing internal working fluid from the heat sink to the heat-extraction plate includes pumping the internal working fluid with a fluid pump of the thermal management device.

By recirculating the internal working fluid from proximate the heat-generating component to a remote heat sink in the flow of immersion working fluid, larger and/or more efficient thermal management devices can be used irrespective of packaging limitations of or near the heat-generating component.

### Industrial Applicability

The present disclosure relates generally to systems and methods for thermal management of electronic devices or other heat-generating components. A thermal management device immersed in the working fluid transfers heat from the heat-generating components to the working fluid. The thermal transfer rate to the working fluid is based partially on a temperature difference between the thermal management device coupled to the heat-generating component and the working fluid. For example, a larger temperature difference creates a higher thermal transfer rate. Positioning the heat exchanger or heat exchange structure in a cooler region of the working fluid can increase the thermal management capacity of a thermal management device. Efficient transfer of heat from the heat-generating component to an immersion working fluid can allow a greater thermal management capacity for the same surface area and/or volume of thermal management devices.

Thermal management devices, according to the present disclosure, may be used in an immersion cooling system to increase the efficiency of the immersion cooling system. Immersion chambers surround the heat-generating components in a liquid working fluid, which conducts heat from the heat-generating components to cool the heat-generating components. As the immersion working fluid absorbs heat from the heat-generating components, the temperature of the immersion working fluid increases. In some embodiments, the hot immersion working fluid can be circulated through the thermal management system to cool the immersion working fluid and/or replace the immersion working fluid with cool immersion working fluid. In some embodiments, the immersion working fluid vaporizes, introducing vapor into the liquid of the immersion working fluid which rises out of the liquid phase, carrying thermal energy away from the heat-generating components in the vapor phase via the latent heat of boiling.

In large-scale computing centers, such as cloud-computing centers, data processing centers, data storage centers, or other computing facilities, immersion cooling systems provide an efficient method of thermal management for many computing components under a variety of operating loads. In some embodiments, an immersion cooling system includes an immersion working fluid in an immersion chamber and a heat exchanger to cool the liquid phase and/or a condenser to extract heat from the vapor phase of the working fluid. The heat exchanger may include a condenser that condenses the vapor phase of the working fluid into a liquid phase and returns the liquid immersion working fluid to the immersion chamber. In some embodiments, the liquid immersion working fluid absorbs heat from the heat-generating components, and one or more fluid conduits direct the hot liquid immersion working fluid outside of the immersion chamber to a radiator, heat exchanger, or region of lower temperature to cool the liquid working fluid.

In some embodiments, a high-compute application assigned to and/or executed on the computing devices or systems in the immersion cooling system requires a large amount of thermal management. A dual phase immersion working fluid boiling absorbs heat to overcome the latent heat of boiling. The phase change from liquid to vapor, therefore, allows the working fluid to absorb a comparatively large amount of heat with a small or no associated increase in temperature. Further, the lower density allows the vapor to be removed from the immersion bath efficiently to exhaust the associated heat from the system.

In some embodiments, a thermal management system includes an immersion tank with a dual phase immersion working fluid positioned therein. The dual phase immersion working fluid receives heat from heat-generating components immersed in the liquid immersion working fluid, and the heat vaporizes the immersion working fluid, changing the immersion working fluid from a liquid phase to a vapor phase. The thermal management system includes a condenser, such as described herein, to condense the vapor immersion working fluid back into the liquid phase. In some embodiments, the condenser is in fluid communication with the immersion tank by one or more conduits. In some embodiments, the condenser is positioned inside the immersion tank.

In some embodiments, the thermal management capacity of a thermal management system is based at least partially on the efficient transfer of heat from the heat-generating components to the immersion working fluid. In space-constrained structures or assemblies, the size (surface area, mass, and/or volume) or the thermal efficiency of the heat sink or thermal management device in contact with the heat-generating component is limited. The ability for the thermal management device coupled to the heat-generating component is hindered. In some embodiments according to the present disclosure, a thermal management device includes an internal working fluid that transfers heat from the heat-generating component to a remote heat sink in a region of cooler immersion working fluid, a region with more space for a larger heat sink than would be possible proximate the heat-generating component, other benefits, or combinations thereof.

A conventional immersion cooling system includes an immersion tank containing an immersion chamber and a condenser or heat-exchanger in the immersion chamber. The immersion chamber contains an immersion working fluid that has a liquid working fluid 108 and a vapor working fluid portion. The liquid working fluid creates an immersion bath in which a plurality of heat-generating components is positioned to heat the liquid working fluid on supports.

In some embodiments, an immersion cooling system includes an immersion tank defining an immersion chamber with an immersion working fluid positioned therein. An immersion working fluid in the immersion tank has a boiling temperature that is at least partially related to one or more operating properties of the immersion cooling system, the electronic components and/or computing devices in the immersion tank, computational or workloads of the electronic components and/or computing devices in the immersion tank, external and/or environmental conditions, or other properties that affect the operation of the immersion cooling system.

In some embodiments, the immersion working fluid is a single-phase working fluid with a boiling temperature below an operating temperature of the heat-generating components that allows the immersion working fluid to remain a liquid working fluid throughout operation. In some embodiments, the immersion working fluid transitions between a liquid immersion working fluid phase and a vapor immersion working fluid phase to remove heat from hot or heat-generating components in the immersion chamber. The liquid immersion working fluid more efficiency receives heat from the heat-generating components and, upon transition to the vapor immersion working fluid, the vapor immersion working fluid can be removed from the immersion tank, cooled and condensed by the condenser (or other heat exchanger) to extract the heat from the immersion working fluid, and the liquid immersion working fluid can be returned to the liquid immersion bath.

In some embodiments, the immersion bath of the liquid immersion working fluid has a plurality of heat-generating components positioned in the liquid immersion working fluid. The liquid immersion working fluid surrounds at least a portion of the heat-generating components and other objects or parts attached to the heat-generating components. In some embodiments, the heat-generating components are positioned in the liquid immersion working fluid on one or more supports. The support may support one or more heat-generating components in the liquid immersion working fluid and allow the immersion working fluid to move around the heat-generating components. In some embodiments, the support is thermally conductive to conduct heat from the heat-generating components. The support(s) may increase the effective surface area from which the liquid immersion working fluid may remove heat through convective cooling.

In some embodiments, the heat-generating components include electronic or computing components or power supplies. In some embodiments, the heat-generating components include computer devices, such as individual personal computer or server blade computers. In some embodiments, one or more of the heat-generating components includes a thermal management device or other device attached to the heat-generating component to conduct away thermal energy and effectively increase the surface area of the heat-generating component according to embodiments of the present disclosure. In some embodiments, the thermal management device of the heat-generating component includes an internal working fluid that flows through a fluid conduit connected to a remote heat sink away from the heat-generating component.

As described, conversion of the liquid immersion working fluid to a vapor phase requires the input of thermal energy to overcome the latent heat of vaporization and may be an effective mechanism to increase the thermal capacity of the working fluid and remove heat from the heat-generating components. Because the vapor immersion working fluid rises in the liquid immersion working fluid, the vapor immersion working fluid can be extracted from the immersion chamber in an upper vapor region of the chamber. A condenser cools part of the vapor immersion working fluid back into a liquid immersion working fluid, removing thermal energy from the system and reintroducing the immersion working fluid into the immersion bath of the liquid immersion working fluid. The condenser radiates or otherwise dumps the thermal energy from the immersion working fluid into the ambient environment or into a conduit to carry the thermal energy away from the cooling system.

In some embodiments of immersion cooling systems, a liquid-cooled condenser is integrated into the immersion tank and/or the chamber to efficiency remove the thermal energy from the working fluid. In some embodiments, an immersion cooling system for thermal management of computing devices allows at least one immersion tank and/or chamber to be connected to and in fluid communication with an external condenser. In some embodiments, an immersion cooling system includes a vapor return line that connects the immersion tank to the condenser and allows vapor working fluid to enter the condenser from the immersion tank and/or chamber and a liquid return line that connects the immersion tank to the condenser and allows liquid working fluid to return to the immersion tank and/or chamber.

The vapor return line may be colder than the boiling temperature of the working fluid. In some embodiments, a portion of the vapor working fluid condenses in the vapor return line. The vapor return line can, in some embodiments, be oriented at an angle such that the vapor return line is non-perpendicular to the direction of gravity. The condensed working fluid can then drain either back to the immersion tank or forward to the condenser depending on the direction of the vapor return line slope. In some embodiments, the vapor return line includes a liquid collection line or valve, like a bleeder valve, that allows the collection and/or return of the condensed working fluid to the immersion tank or condenser.

In some embodiments, the liquid working fluid receives heat in a cooling volume of working fluid immediately surrounding the heat-generating components. The cooling volume is the region of the working fluid (including both liquid and vapor phases) that is immediately surrounding the heat-generating components and/or the thermal management device(s) thermally coupled thereto and is responsible for the convective cooling of the heat-generating components. In some embodiments, the cooling volume is the volume of working fluid within 5 millimeters (mm) of the heat-generating components and/or thermal management device(s).

The immersion working fluid has a boiling temperature below a critical temperature at which the heat-generating components experience thermal damage. The immersion working fluid can thereby receive heat from the heat-generating components to cool the heat-generating components before the heat-generating components experience damage.

For example, the heat-generating components may be computing components that experience damage above 100° Celsius (C). In some embodiments, the boiling temperature of the immersion working fluid is less than a critical temperature of the heat-generating components. In some embodiments, the boiling temperature of the immersion working fluid is less about 90° C. at 1 atmosphere of pressure. In some embodiments, the boiling temperature of the immersion working fluid is less about 80° C. at 1 atmosphere of pressure. In some embodiments, the boiling temperature of the immersion working fluid is less about 70° C. at 1 atmosphere of pressure. In some embodiments, the boiling temperature of the immersion working fluid is less about 60° C. at 1 atmosphere of pressure. In some embodiments, the boiling temperature of the immersion working fluid is at least about 35° C. at 1 atmosphere of pressure. In some embodiments, the working fluid includes water.

In some embodiments, the working fluid includes glycol. In some embodiments, the working fluid includes a combination of water and glycol. In some embodiments, the working fluid includes an aqueous solution. In some embodiments, the working fluid includes an electronic liquid, such as FC-72 available from 3M, or similar non-conductive fluids. In some embodiments, the heat-generating components, supports, or other elements of the immersion cooling system positioned in the working fluid have nucleation sites on a surface thereof that promote the nucleation of vapor bubbles of the working fluid at or below the boiling temperature of the working fluid.

In some embodiments, a thermal management device includes a heat-extraction plate thermally coupled to a heat-generating component. While embodiments of thermal management devices will be described in relation to processors (e.g., central processing unit (CPU), graphical processing unit (GPU), physics processing unit, application specific integrated circuit (ASIC)), as described above, the heat-generating component may be any heat-generating component in an immersion cooling system, such as a power supply, hardware storage device, networking or other communication device, etc. In some embodiments, the heat-extraction plate is configured to be thermally coupled, at a proximal surface of the heat-extraction plate of the thermal management device, to a heat-generating component. In some embodiments, the thermal management device is directly coupled to the heat-generating component. For example, the thermal management device may be directly contacting the heat-generating component on a proximal surface of the heat-extraction plate. In some embodiments, the thermal management device is indirectly thermally coupled to the heat-generating component. For example, the thermal management device may be thermally coupled to the heat-generating component by a thermal interface material, such as thermal paste, positioned between a proximal surface of the heat-extraction plate of the thermal management device and the heat-generating component. In some examples, the thermal management device may be thermally coupled to the heat-generating component by a liquid phase metal positioned between a proximal surface of the heat-extraction plate of the thermal management device and the heat-generating component. In some examples, the thermal management device may be thermally coupled to the heat-generating component by a heat spreader positioned between a proximal surface of the heat-extraction plate of the thermal management device and the heat-generating component.

In some embodiments, the heat-extraction plate is thermally coupled to a heat sink by a fluid conduit. An internal working fluid inside the thermal management device flows between the heat-extraction plate and the heat sink via the fluid conduit to transfer heat from the heat-extraction plate (received from the heat-generating component) to the remotely located heat sink.

In some embodiments, the heat sink is positioned in a downstream flow direction of a surrounding liquid immersion working fluid (such as that described herein). In some embodiments, the heat sink includes a plurality of thermal transfer features, such as fins, rods, pins, surface treatments, coatings, etc. that increase surface area, thermal transfer efficiency, vapor bubble nucleation, or otherwise facilitate the exhaustion of heat from the heat sink to the liquid immersion working fluid. As described herein, in some embodiments, the liquid immersion working fluid vaporizes into a vapor immersion working fluid. In some embodiments, the liquid immersion working fluid remains in a liquid phase while increasing in temperature. By positioning the heat sink downstream of the heat-extraction plate in the flow direction of the immersion working fluid, the first region of the immersion working fluid proximate the heat-extraction plate remains cooler than a second region of the immersion working fluid proximate the heat sink, which allows the heat-generating component to remain cooler and/or exhaust heat to the heat-extraction plate and/or the immersion working fluid more efficiently.

In some embodiments, a thermal management device includes a heat-extraction plate thermally coupled to a heat sink by a plurality of fluid conduits. In some embodiments, the fluid conduits include a vapor conduit and a condensate conduit that circulate a vapor phase of an internal working fluid from the heat-extraction plate to the heat sink and a liquid phase (i.e., condensate) of the internal working fluid from the heat sink back to the heat-extraction plate. The heat-extraction plate receives heat from heat-generation component to vaporize the internal working fluid, and the heat sink exhausts heat from the internal working fluid to condense the internal working fluid into a liquid phase.

In some embodiments, the heat sink circulates the internal working fluid through and/or past a plurality of thermal transfer features to exhaust the heat to the immersion working fluid. In some embodiments, the heat sink includes a combination of thermal transfer features, such as plates or fins that are thermally coupled by heat pipes oriented transversely to the plates or fins.

In some embodiments, the thermal transfer features are positioned in the flow direction of the immersion working fluid and in a downstream direction from the heat-extraction plate. The heat exhausted from the heat sink is therefore exhausted into the immersion working fluid downstream from the heat-extraction plate and the heat-generating component.

In some embodiments, the thermal management device is oriented at least partially vertically with respect to a gravitational direction. In some embodiments, the gravitational direction and the flow direction are substantially opposite one another. When the thermal management device is oriented at least partially vertically with respect to a gravitational direction, the heat sink is vertically above the heat-extraction plate with respect to gravity, allowing the relative buoyancy of the vapor internal working fluid to move the vapor internal working fluid through the vapor conduit toward the heat sink and the relative density of liquid internal working fluid (condensate) to flow downward through the condensate conduit toward the heat-extraction plate.

To further facilitate the thermal siphon of the thermal management device, in some embodiments, the vapor conduit is connected to a vapor port of the heat-extraction plate and the condensate conduit is connected to a condensate port of the heat-extraction plate. The vapor port and the condensate port provide fluid communication to an internal chamber of the heat-extraction plate at different locations relative to the heat sink. When oriented vertically relative to the gravitational direction, the vapor port and the condensate port are positioned at different vertical heights. In some embodiments, the vapor port is located closer to the heat sink than the condensate port. When oriented vertically relative to the gravitational direction, the vapor port is vertically higher than the condensate port. The vertical relationship allows for a gravity-assisted passive circulation of the internal working fluid through the thermal management device.

In some embodiments, a surface area of the heat sink is greater than the surface area of the heat-extraction plate. In some embodiments, the surface area of the heat sink is at least twice that of the surface area of the heat-extraction plate. In some embodiments, the surface area of the heat sink is at least four times that of the surface area of the heat-extraction plate. In some embodiments, the surface area of the heat sink is at least ten times that of the surface area of the heat-extraction plate.

The vapor port is, in some embodiments, closer to the heat sink than the condensate port. In some embodiments, the vapor conduit is shorter in length than the condensate conduit. For example, the vapor conduit between the vapor port and the heat sink is shorter than the condensate conduit between the condensate port and the heat sink. In at least one embodiment, the vapor conduit connects to the heat sink at a first side of the heat sink and the condensate conduit connects to the heat sink at a second side of the heat sink substantially opposite the first side.

In some embodiments, a heat-extraction plate of the thermal management device includes an internal chamber that houses an internal working fluid, such as that described herein. In some embodiments, the internal working fluid is a dual phase working fluid with a liquid phase and a vapor phase during operation of the thermal management device. In some embodiments, the relative density of the liquid internal working fluid and the vapor internal working fluid causes the liquid internal working fluid to settle at a bottom of the internal chamber and the vapor internal working fluid to rise to a top of the internal chamber relative to the gravitational direction. In some embodiments, the vapor port is positioned on the heat-extraction plate proximate the vapor portion of the internal chamber containing the vapor internal working fluid. In some embodiments, the condensate port is positioned on the heat-extraction plate proximate the liquid portion of the internal chamber containing the liquid internal working fluid.

In some embodiments, as the heat-extraction plate and liquid internal working fluid receive heat from the heat-generating component, the internal working fluid changes state and the vapor pressure urges vapor internal working fluid through the vapor port into the vapor conduit. The vapor internal working fluid flows through the vapor conduit to the heat sink, where the heat sink exhausts heat from the internal working fluid (e.g., to the immersion working fluid such as described herein) to condense the vapor internal working fluid to the liquid phase. The condensation contributes to a pressure differential that further circulates the vapor working fluid to the heat sink. In some embodiments, the liquid internal working fluid then flows downward relative to the gravitational direction through the condensate conduit to the condensate port. Upon returning to the internal chamber, the liquid internal working fluid is available to receive heat from the heat-generating component and continue the passive circulation of internal working fluid.

In some embodiments, the heat sink includes a condensation chamber or other fluid chamber or conduit with one or more condensation surface features configured to facilitate condensation of the internal working fluid. In some embodiments, the condensation surface features include pins, rods, fins, pipes, cones, or other surface features that increase surface area, thermal transfer efficiency, condensation rates, or otherwise facilitate the transfer of heat from the vapor internal working fluid to condense the internal working fluid.

In some embodiments, a wicking structure is positioned in the internal chamber of the heat-extraction plate. The wicking structure wicks the liquid internal working fluid into additional portions of the internal chamber to receive heat through the heat-extraction plate. For example, less than the entire internal chamber may have liquid internal working fluid therein, and the wicking structure may draw the liquid internal working fluid in contact with or proximity to additional internal surfaces of the heat-extraction plate to more efficiently transfer heat to the liquid internal working fluid.

In some embodiments, a thermal management device has one or more internal thermal features to facilitate transfer of heat from the heat-generating component to the internal working fluid. In some embodiments, the internal thermal features include pins, rods, fins, pipes, cones, or other surface features that increase surface area, thermal transfer efficiency, vapor bubble nucleation, or otherwise facilitate the transfer of heat to the liquid internal working fluid. In some embodiments, the internal thermal features are positioned on an internal surface proximate a contact surface of the heat-extraction plate. The contact surface is the surface of the heat-extraction plate contacting or configured to contact the heat-generating component. As described herein, the contact surface, in some embodiments, directly contacts the heat-generating component. In some embodiments, the contact surface is indirectly thermally coupled to the heat-generating component by a thermal interface material, such as a paste, gel, or liquid metal that conducts heat from the heat-generating component to the contact surface.

While some embodiments of a thermal management device according to the present disclosure include a dual phase internal working fluid to passively circulate heat through the thermal management device, in some embodiments, the thermal management device is oriented relative to the gravitational direction such that active circulation is needed. In some embodiments, a single-phase internal working fluid is used in the thermal management device, and active circulation moves the internal working fluid through the fluid conduit between the heat-extraction plate and the heat sink.

In some embodiments, the thermal management device includes a fluid pump to actively circulate an internal working fluid through the thermal management device. As described herein, in space-constrained embodiments, the heat sink is located in a region with more space than is available adjacent to the heat-generating component. The heat sink, therefore, has the available volume to house the fluid pump therein, in some embodiments.

In some embodiments, the internal working fluid is a single-phase working fluid. The heat-extraction plate is thermally coupled to the heat-generating component and a first fluid conduit carries the hot internal working fluid from the heat-extraction plate to the heat sink. In some embodiments, the fluid pump then pumps the cooled internal working fluid from the heat sink through a second fluid conduit to the heat-extraction plate. In some embodiments, the internal working fluid is a dual phase working fluid, where the first fluid conduit is a vapor conduit, and the second fluid conduit is a condensate conduit.

In some embodiments, the fluid pump is located in line with the second fluid conduit to pump cooled internal working fluid from the heat sink to the heat-extraction plate. In some embodiments, the heat sink has greater thermal transfer capacity when the fluid pump is located elsewhere in the thermal management device.

In some embodiments, a method of thermal management includes orienting a thermal management device in an immersion working fluid with a remote heat sink positioned downstream in the flow direction from a heat-generating component. In some embodiments, the thermal management device is any embodiment of a thermal management device described herein. In some embodiments, the immersion working fluid is a single-phase immersion working fluid. In some embodiments, the immersion working fluid is a dual phase immersion working fluid. In some embodiments, orienting the thermal management device further includes orienting the heat sink above a heat-extraction plate of the thermal management device relative to a gravitational direction. In some embodiments, orienting the thermal management device further includes orienting the thermal management device in the flow direction where the flow direction is substantially opposite the gravitational direction.

The method further includes heating an internal working fluid of the thermal management device at a heat-extraction plate with heat from the heat-generating component. The method, in some embodiments, includes flowing hot internal working fluid from the heat-extraction plate to the remote heat sink. In some embodiments, the hot internal working fluid is vapor internal working fluid. In some embodiments the hot internal working fluid is liquid internal working fluid.

The method further includes exhausting heat from the internal working fluid to the immersion working fluid at the remote heat sink. In some embodiments, exhausting heat from the internal working fluid includes lower a temperature of the internal working fluid. In some embodiments, exhausting heat from the internal working fluid includes condensing the internal working fluid. In some embodiments, the method includes flowing internal working fluid from the heat sink to the heat-extraction plate. In some embodiments, flowing internal working fluid from the heat sink to the heat-extraction plate includes allowing the internal working fluid to flow down a fluid conduit under the force of gravity. In some embodiments, flowing internal working fluid from the heat sink to the heat-extraction plate includes pumping the internal working fluid with a fluid pump of the thermal management device.

By recirculating the internal working fluid from proximate the heat-generating component to a remote heat sink in the flow of immersion working fluid, larger and/or more efficient thermal management devices can be used irrespective of packaging limitations of or near the heat-generating component.

The present disclosure relates to systems and methods for cooling electronic components and/or devices according to at least the examples provided in the sections below:

Clause 1. A thermal management system comprising: an immersion working fluid having a flow direction; a heat extraction plate with an internal chamber therein; an internal working fluid positioned in the heat extraction plate; and a heat sink in fluid communication with the internal chamber by at least one fluid conduit, wherein the heat sink is downstream from the heat extraction plate in the flow direction.

Clause 2. The thermal management system of clause 1, wherein the internal working fluid is a dual phase working fluid.

Clause 3. The thermal management system of clause 1, wherein the internal working fluid is a single-phase working fluid.

Clause 4. The thermal management system of clause 1, wherein the immersion working fluid is a dual phase working fluid.

Clause 5. The thermal management system of clause 1, wherein the immersion working fluid is a single-phase working fluid.

Clause 6. The thermal management system of clause 1, wherein the at least one fluid conduit includes a vapor conduit providing fluid communication of a vapor phase of the internal working fluid toward the heat sink and a condensate conduit providing fluid communication of a liquid phase of the internal working fluid toward the heat extraction plate.

Clause 7. The thermal management system of clause 1, wherein the flow direction of the immersion working fluid is opposite a gravitational direction.

Clause 8. The thermal management system of clause 1, further comprising at least one fluid pump in fluid communication with the internal working fluid to move the internal working fluid through the at least one fluid conduit.

Clause 9. The thermal management system of clause 8, wherein the at least one fluid pump is located in the heat sink.

Clause 10. The thermal management system of clause 1, wherein the heat extraction plate includes one or more thermal surface features on an internal surface defining the internal chamber therein to facilitate heat exchange rate.

Clause 11. The thermal management system of clause 1, wherein the heat extraction plate includes one or more wicking structures in the internal chamber therein to facilitate movement of the internal working fluid therein.

Clause 12. The thermal management system of clause 1, wherein the heat sink includes a plurality of fins oriented in the flow direction.

Clause 13. A thermal management system comprising: a thermal management device including: a heat-extraction plate with an internal chamber therein; an internal working fluid positioned in the heat-extraction plate; a heat sink in fluid communication with the internal chamber; a vapor conduit providing fluid communication from a vapor port of the internal chamber to the heat sink; and a condensate conduit providing fluid communication from the heat sink to a condensate port of the internal chamber, wherein the vapor port is closer to the heat sink than the condensate port.

Clause 14. The thermal management system of clause 13, wherein the thermal management device is coupled to a heat-generating component of an electronic device with the heat sink oriented above the heat-extraction plate relative to a gravitational direction.

Clause 15. The thermal management system of clause 13, further comprising: an immersion working fluid having a flow direction, wherein the heat sink is downstream from the heat-extraction plate in the flow direction.

Clause 16. The thermal management system of clause 13, wherein the heat sink includes a condensation chamber, and the condensation chamber includes one or more condensation surface features configured to facilitate condensation of the internal working fluid.

Clause 17. The thermal management system of clause 13, further comprising a wicking structure in the internal chamber of the heat-extraction plate.

Clause 18. A method of thermal management comprising: orienting a thermal management device in an immersion working fluid with a remote heat sink positioned downstream in a flow direction from a heat-generating component; heating an internal working fluid of the thermal management device at a heat-extraction plate with heat from the heat-generating component; flowing hot internal working fluid from the heat-extraction plate to the remote heat sink; exhausting heat from the internal working fluid to the immersion working fluid at the remote heat sink; and flowing internal working fluid from the heat sink to the heat-extraction plate.

Clause 19. The method of clause 18, wherein heating the internal working fluid of the thermal management device includes vaporizing the internal working fluid.

Clause 20. The method of clause 18, wherein flowing internal working fluid from the heat sink to the heat-extraction plate includes allowing the internal working fluid to flow downward under a force of gravity.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about”, “substantially”, or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A thermal management system comprising:
an immersion working fluid having a flow direction;
a heat extraction plate with an internal chamber therein;
an internal working fluid positioned in the heat extraction plate; and
a heat sink in fluid communication with the internal chamber by at least one fluid conduit, wherein the heat sink is downstream from the heat extraction plate in the flow direction.

2. The thermal management system of claim 1, wherein the internal working fluid is a dual phase working fluid.

3. The thermal management system of claim 1, wherein the internal working fluid is a single-phase working fluid.

4. The thermal management system of claim 1, wherein the immersion working fluid is a dual phase working fluid.

5. The thermal management system of claim 1, wherein the immersion working fluid is a single-phase working fluid.

6. The thermal management system of claim 1, wherein the at least one fluid conduit includes a vapor conduit providing fluid communication of a vapor phase of the internal working fluid toward the heat sink and a condensate conduit providing fluid communication of a liquid phase of the internal working fluid toward the heat extraction plate.

7. The thermal management system of claim 1, wherein the flow direction of the immersion working fluid is opposite a gravitational direction.

8. The thermal management system of claim 1, further comprising at least one fluid pump in fluid communication with the internal working fluid to move the internal working fluid through the at least one fluid conduit.

9. The thermal management system of claim 8, wherein the at least one fluid pump is located in the heat sink.

10. The thermal management system of claim 1, wherein the heat extraction plate includes one or more thermal surface features on an internal surface defining the internal chamber therein to facilitate heat exchange rate.

11. The thermal management system of claim 1, wherein the heat extraction plate includes one or more wicking structures in the internal chamber therein to facilitate movement of the internal working fluid therein.

12. The thermal management system of claim 1, wherein the heat sink includes a plurality of fins oriented in the flow direction.

13. A thermal management system comprising:
a thermal management device including:
a heat-extraction plate with an internal chamber therein;
an internal working fluid positioned in the heat-extraction plate;
a heat sink in fluid communication with the internal chamber;
a vapor conduit providing fluid communication from a vapor port of the internal chamber to the heat sink; and
a condensate conduit providing fluid communication from the heat sink to a condensate port of the internal chamber, wherein the vapor port is closer to the heat sink than the condensate port.

14. The thermal management system of claim 13, wherein the thermal management device is coupled to a heat-generating component of an electronic device with the heat sink oriented above the heat-extraction plate relative to a gravitational direction.

15. The thermal management system of claim 13, further comprising:
an immersion working fluid having a flow direction, wherein the heat sink is downstream from the heat-extraction plate in the flow direction.

16. The thermal management system of claim 13, wherein the heat sink includes a condensation chamber, and the condensation chamber includes one or more condensation surface features configured to facilitate condensation of the internal working fluid.

17. The thermal management system of claim 13, further comprising a wicking structure in the internal chamber of the heat-extraction plate.

18. A method of thermal management comprising:
orienting a thermal management device in an immersion working fluid with a remote heat sink positioned downstream in a flow direction from a heat-generating component;
heating an internal working fluid of the thermal management device at a heat-extraction plate with heat from the heat-generating component;
flowing hot internal working fluid from the heat-extraction plate to the remote heat sink;
exhausting heat from the internal working fluid to the immersion working fluid at the remote heat sink; and
flowing internal working fluid from the heat sink to the heat-extraction plate.

19. The method of claim 18, wherein heating the internal working fluid of the thermal management device includes vaporizing the internal working fluid.

20. The method of claim 18, wherein flowing internal working fluid from the heat sink to the heat-extraction plate includes allowing the internal working fluid to flow downward under a force of gravity.
